(19) United States
(12) Patent Application Publication
(10) Pub. No.: US 2009/0101206 A1
(43) Pub. Date: Apr. 23, 2009

(54) PROCESS FOR MANUFACTURING A PHOTOVOLTAIC OR A LIGHT EMITTING POLYMER DEVICE

(75) Inventor: Mladen Diklich, Mission (CA)

Correspondence Address: BORDEN LADNER GERVAIS LLP, 1200 WATERFRONT CENTRE, 200 BURRARD ST., P.O. BOX 48600, VANCOUVER, BC, V7X 1T2, CA

(73) Assignee: QUANTUM SOLAR SYSTEM CORP, Mission (CA)

(21) Appl. No.: 11/874,055

(22) Filed: Oct. 17, 2007

(51) Int. Cl. H01L 31/055; H01L 31/05

(52) U.S. Cl. 136/257; 136/247

(57) ABSTRACT

A process for manufacturing a photovoltaic, or a light emitting polymer device, comprises providing a cathode of aluminum, placing the cathode in an inert atmosphere and removing aluminum oxide formed on the aluminum prior to placement thereof in the inert atmosphere. The aluminum is passivated while still in the inert atmosphere by coating the aluminum with a passivation agent to prevent oxidation of the aluminum upon exposure to oxygen. The passivated aluminum is removed from the inert atmosphere and an active layer of a photovoltaic or an electroluminescent material is provided on the passivated aluminum. A valence hole injection layer is then provided over the active layer to form an anode. In one embodiment, the cathode comprises a plurality of electrically isolated cathode cells which are cut from an aluminum sheet or foil and wherein the active layer and valence hole injection layer are printed over the cathode cells.

### FIELD OF THE INVENTION

This invention relates to a process for manufacturing a photovoltaic device or an electroluminescent device, and devices produced by the process.

### BACKGROUND OF THE INVENTION

A photovoltaic device, such as a photovoltaic cell, generates electric power when exposed to light, whereas an electroluminescent device, such as a polymer light emitting diode (PLED) emits light when electrical power is applied.

Basically, such devices comprise an active layer enclosed between two electrodes and at least one electrode must be transparent or semi-transparent to allow the passage of light. Such devices can also include charge transporting layers to improve the stability and efficiency of the device, as well as a hole injection layer (HIL) to enhance operation of the device.

In recent developments, the active layer comprises a conjugated polymer that is printed, e.g. by screen printing, as a thin layer onto a substrate. In the case of a photovoltaic device, the active layer may comprise a quantum dot or fullerene embedded within a light emitting polymer, and in the case of an electroluminescent device, the active layer may comprise a light emitting polymer or a tuned quantum dot embedded within a light emitting polymer.

As described in U.S. Pat. No. 6,605,483, (the '483 patent), the hole injection layer consists of a conductive polymer which is printed on an indium tin-oxide (i.t.o.) or other high work function transparent electrode which is supported by a substrate.

In the process described in the '483 patent, the device is built from the anode up. That is the hole injection layer is deposited on the indium tin-oxide, the active layer is then deposited on the hole injection layer, trace circuitry and a dielectric isolation layer are deposited around the edge of the active layer, after which a top conductive electrode, which is typically aluminum or magnesium-silver alloy, is vapor phase deposited onto the active layer.

The above described process is the so-called forward-build process and it has the disadvantage that the step of vapor depositing the cathode, which involves working under a vacuum, is an expensive process making the manufacture unattractive.

The '483 patent also refers to the possibility of using a reverse-build process in which the cathode is first vapor phase deposited onto a plastic or other substrate, again involving the expensive step of working in a vacuum, then followed by screen printing the other layers in reverse sequence as opposed to the forward-build method.

It is also conjectured that, as an alternative to the vapor deposition of the cathode, a foil cathode of aluminum could be selected mounted to a substrate so that it is possible to screen print directly onto the foil. The following step in the process, as described in the patent, is the screen printing of a light emitting layer onto the cathode and there is no teaching of any intervening step to address the electrical conductivity of the aluminum foil.

The problem with this suggested approach is that the aluminum is oxidized when exposed to air, resulting in the formation of an aluminum oxide layer on the cathode. Since aluminum oxide is a non-conducting dielectric, the resulting device will not operate or operates at a reduced efficiency, since electron flow from the cathode will not be possible or restricted.

It is an object of the present invention to provide an inexpensive and simplified method of producing a photovoltaic or light emitting polymer device using aluminum foil in combination with screen or other manner of printing in the open air, while overcoming the abovementioned problems of the prior art.

### SUMMARY OF THE INVENTION

According to the invention there is provided a process for manufacturing a photovoltaic or a light emitting polymer device, comprising: providing a cathode of aluminum; placing the cathode in an inert atmosphere and removing aluminum oxide formed on the aluminum prior to placement thereof in the inert atmosphere; passivating the aluminum while still in the inert atmosphere by coating the aluminum with a passivation agent to prevent oxidation of the aluminum upon exposure to oxygen; removing the passivated aluminum from the inert atmosphere; providing an active layer of a photovoltaic or an electroluminescent material on the passivated aluminum; and providing a valence hole injection layer over the active layer to form an anode.

The inert atmosphere may comprise a gas such as nitrogen or argon.

The step of removing aluminum oxide from the aluminum may comprise treating the aluminum with a suitable etching medium, such as nitric acid.

The passivation agent may comprise an alkyl ether acetate, such as butyl carbitol acetate.

The cathode may be in the form of an aluminum sheet or foil. The active layer may be printed on the aluminum sheet or foil by means of screen printing, ink jet printing or gravure printing (rotogravure).

A solution for use in printing the active layer may comprise a conjugated organic polymer dissolved in a suitable solvent. It may also contain a fullerene and/or quantum dot material. For example, the solution may be prepared by dissolving a polythiophene, such as P3HT (3-hexylthiophene) in the form of flakes in suitable solvents, such as dichlorobenzene and THF (tetrahydrofuran) and mixing in a fullerene or fullerence derivative, such as phenyl-C61-butyricacid-methylester (PCBM).

An alternative example is to use a polythiophene, such as MDMO-PPV (poly[2-methoxy-5-(3′,7′-dimethyl-octyloxy)-p-phenylene vinylene]) in flake form dissolved in toluene and THF with quantum dot material mixed in.

The hole injection layer may be printed on the active layer by means of screen printing, ink jet printing or gravure printing.

The cathode may comprise a plurality of electrically isolated cathode cells which are cut from an aluminum sheet or foil and mounted on a substrate.

Also according to the invention there is provided a process for manufacturing a photovoltaic or a light emitting polymer device, comprising: providing a plurality of electrically isolated cathode cells of aluminum sheet or foil on a substrate; placing the substrate with the electrically isolated cathode cells in an inert atmosphere and removing aluminum oxide formed on the cathode cells prior to placement thereof in the inert atmosphere; passivating the cathode cells while still in the inert atmosphere by coating the cathode cells with a passivation agent to prevent oxidation of the cathode cells upon exposure to oxygen; removing the passivated cathode cells from the inert atmosphere; printing discrete segments of an active layer of a photovoltaic or an electroluminescent material over each of the cathode cells; and printing discrete segments of a valence hole injection layer over each of the segments of the active layer to form an anode for each cathode cell.

Further objects and advantages of the invention will become apparent from the description of preferred embodiments of the invention below.

### BRIEF DESCRIPTION OF THE DRAWINGS

The invention will now be described, by way of example, with reference to the accompanying drawings, in which:

FIG. 1 is a sectional side view of a photovoltaic device;

FIG. 2 is a sectional side view showing another photovoltaic device in which three of the devices of FIG. 1 are connected in series;

FIG. 3 shows eight discrete cathode cells etched out of aluminum sheet or foil;

FIG. 4 shows an insulator that has been screen printed around the cathode cells of FIG. 3;

FIG. 5 shows eight discrete segments of an active layer that are printed over the cathode cells of FIG. 3;

FIG. 6 shows eight strips of insulator that are printed along one side of each of the active layer segments;

FIG. 7 shows eight discrete segments of a hole injection layer that are printed over the active layer segments;

FIG. 8 shows electrically conductive material that is printed to interconnect the cathode cells;

FIG. 9 is a plan view of a completed photovoltaic device; and

FIG. 10 is a plan view of a photovoltaic device with an alternative layout of cells.

### DETAILED DESCRIPTION OF THE INVENTION

The process described in this example is a reverse-build process where a photovoltaic device 10 is built from the cathode up.

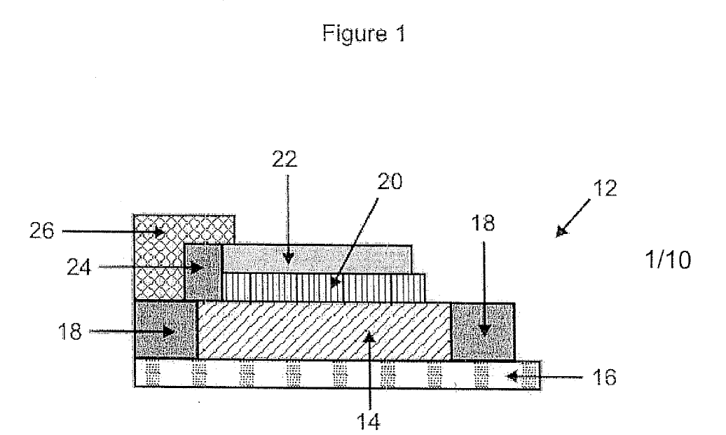

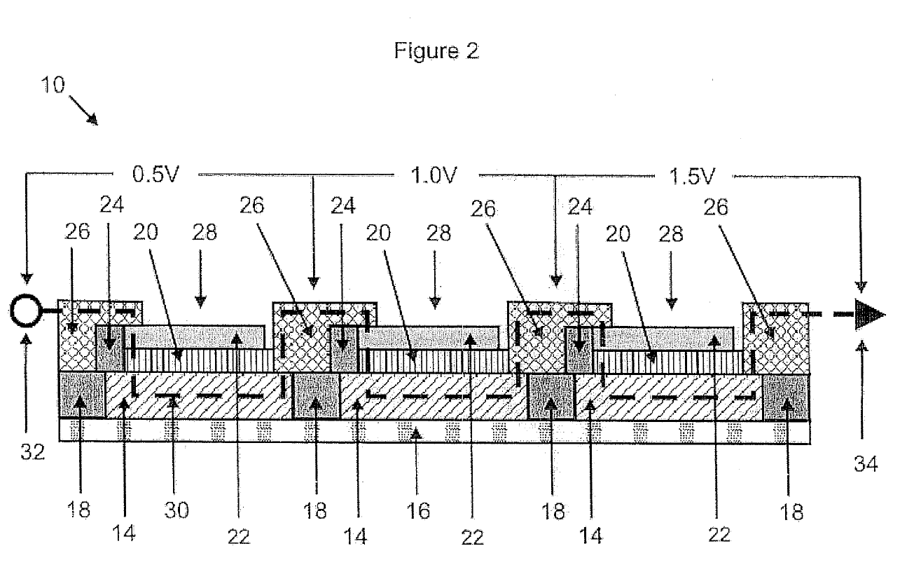

The device 10 shown in FIG. 2 comprises three photovoltaic cells 12, as shown in FIG. 1, connected in series.

The cells 12 comprise a cathode 14 of aluminum foil mounted on a substrate material 16 suitable for screen printing, such as a polycarbonate, an acrylic, wood, metal or paper. A dielectric, insulating filler material 18 surrounds the cathode 14 and has the same height as the cathode 14. The material 18 may be a urethane based UV curable or oven-curable solvent based compound, such as barium titanite (BaTiO₃). An active layer 20 is located on the cathode 14 and a hole injection layer 22, forming the anode, is located over the active layer 20.

Dielectric insulating material 24 is provided along one side of the layers 20 and 22 to prevent short-circuiting, if necessary, and a conductive interconnect material 26 is provided for electrical contact with the cell 12 and for connecting a series of the cells 12 together, as shown in FIG. 2. The insulating material 24 may be the same as the material 18 and the conductive material 26 may be oven-curable solvent based silver, gold, copper, nickel, graphite conductor or urethane based UV curable silver, gold, copper, graphite or nickel conductor.

As an alternative, the insulating material 24 can be omitted, provided the hole injection layer 22 is large enough in area to cover the active layer 20 and adheres to the filler material 18 and is not in contact with the cathode 14.

Incoming light (photons) is indicated by the arrows 28 and the flow of electric current is shown by the broken line 30 in FIG. 2. A transparent or semi-transparent protective or covering layer (not shown) can be provided as a top layer over the device 10. The positive pole of the device 10 is at 32 and the negative pole at 34. In the present example, each of the cells 12 generates a voltage potential difference of 0.5 v, so that the total over the three cells 12 is 1.5 v.

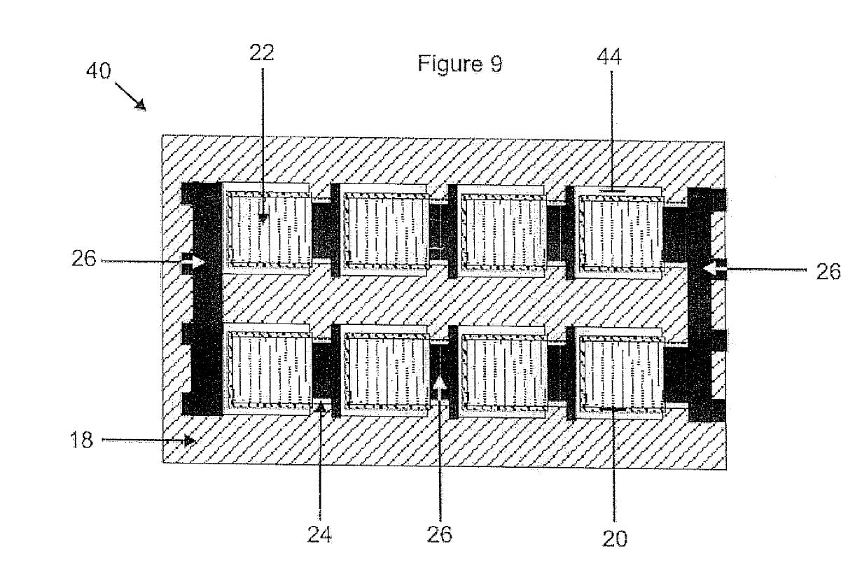

Having now described the basic layout of the device 10, a method for manufacturing the device will be described. In describing the method, a photovoltaic device 40 having eight of the cells 12 will be taken as an example. See FIG. 9.

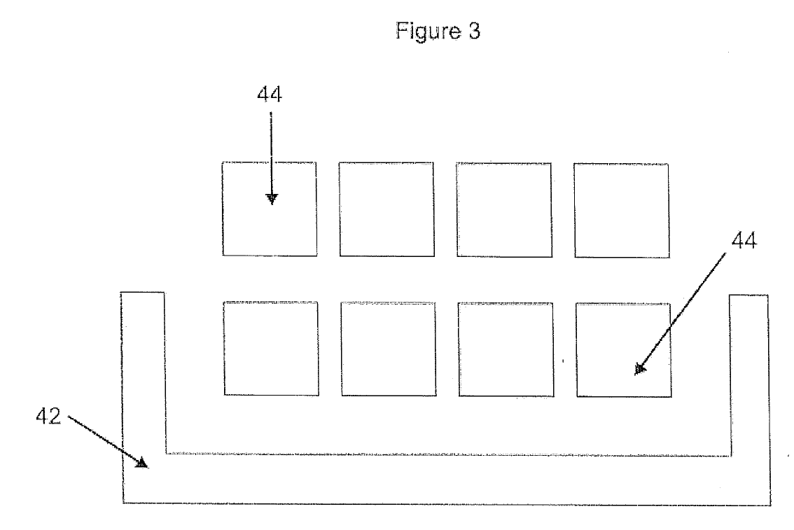

To form the cathodes 14 of the cells 12, aluminum sheet or foil 42 which may have an adhesive backing is engraved with a digital cutter to create precise electrically isolated cathode cells 44, as shown in FIG. 3.

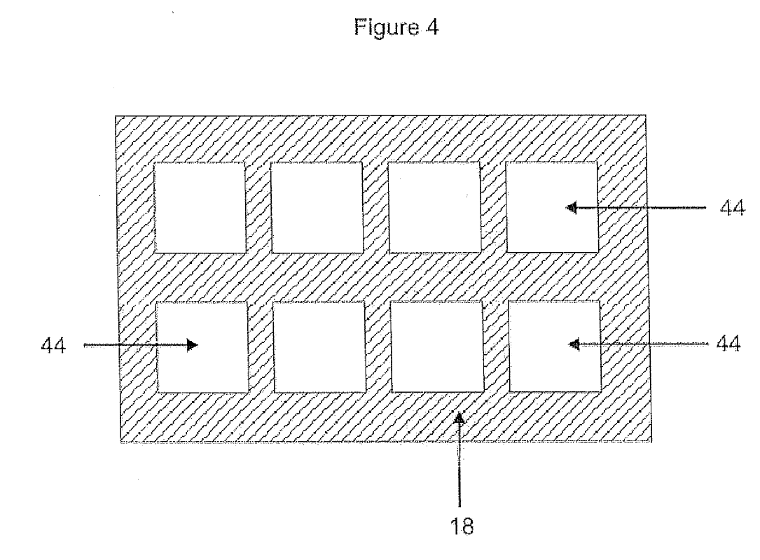

The cathode cells 44 are transferred to the substrate 16 suitable for screen printing. One method of achieving this is to apply pick-up tape to the top surface of the cathode cells 44 and then to peel the tape away from the aluminum sheet 42, taking away with it the cathode cells 44 with the adhesive side exposed. The cathode cells 44 on the pick-up tape are placed with the adhesive side down onto the substrate which is suitable for screen printing. The dielectric filler layer 18 is then screen printed around the electrically isolated cathode cells 44 as shown in FIG. 4.

An alternative method would be to die cut or employ a vinyl cutting machine to cut around the aluminum foil 42 and remove the excess aluminum from the existing substrate leaving behind electrically isolated islands of aluminum 44 the same as in the step above with the option of depositing the dielectric filler 18 onto the aluminum foil substrate.

The filler layer 18 of dielectric material, such as a urethane-based dielectric material, is of the same thickness as the cathode cells 44 to facilitate smooth, even printing across both the substrate and the aluminum cathode cells 44.

The substrate with the cathode cells 44 and dielectric filler 18 is placed under a nitrogen blanket in a glove box and the aluminum is de-oxidized, i.e. aluminum oxide is removed from the surface of the aluminum, by applying an etch that will not affect the dielectric layer 18. This can be achieved by using a cloth with nitric acid thereon. The deoxidized aluminum is then cleaned by washing with de-ionized water.

Whilst still in the glove box under the nitrogen blanket, after the aluminum has been de-oxidized and cleaned, the aluminum is passivated so that it will not become reactive to oxidation when exposed to the open air. This is achieved by coating it with a passivation agent, such as an alkyl ether acetate, an example of which is butyl carbitol acetate (C₁₀H₂₀O₄), which is compatible with the next step in the process.

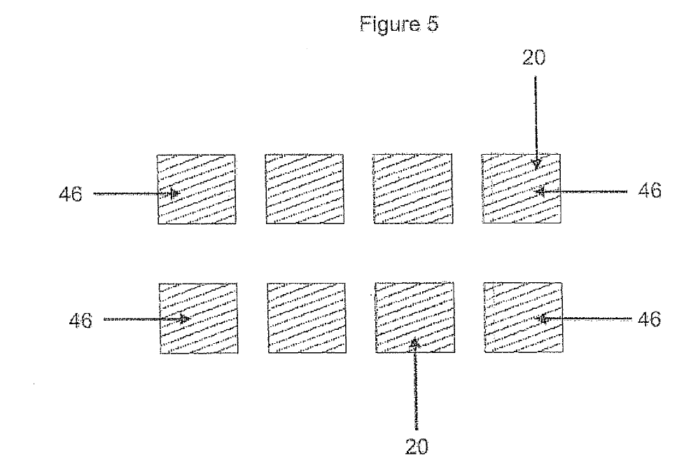

The next step is the printing of the active layer 20 over the cathode cells 44. The active layer 20 is printed in separate segments 46, shown in FIG. 5, over the cells 44. As shown, the segments 46 are of a smaller size than the cells 44 (compare with FIGS. 3 and 4).

In order to produce a solution for printing the active layer 20, active layer polymer flake (P3HT) is opened under a nitrogen blanket in the glove box. A magnetic stir bar along with the polymer flake is placed in a flask along with appropriate solvents, such as dichlorobenzone and THF, and capped with a stopper having two openings, the one opening being connected to a source of nitrogen and the other opening acting as exhaust. In this way, the flask is maintained filled with nitrogen so as not to oxidize the polymer prior to being dissolved. The flask is then removed to an open air environment and placed on a heated magnetic stirrer. The stopper with the nitrogen source is utilized for economic purposes since the volume of the flask is considerably less than the volume of the glove box.

When the active layer polymer is in solution, the flask is returned to the glove box under the nitrogen blanket where blended Fullerene polymer (PCBM) is added. The stopper with the nitrogen connection is again placed on the flask to fill the flask with nitrogen, whereupon the flask is removed from the glove box and returned to the magnetic stirrer for further mixing to result in the solution for printing the active layer.

The active layer 20 comprising P3HT and PCBM or MDMO-PPV with Quantum Dots is screen printed over the electrically isolated, passivated aluminum cathodes 44 and cured in a convection oven leaving the aluminum under the active layer 20 in a de-oxidized state.

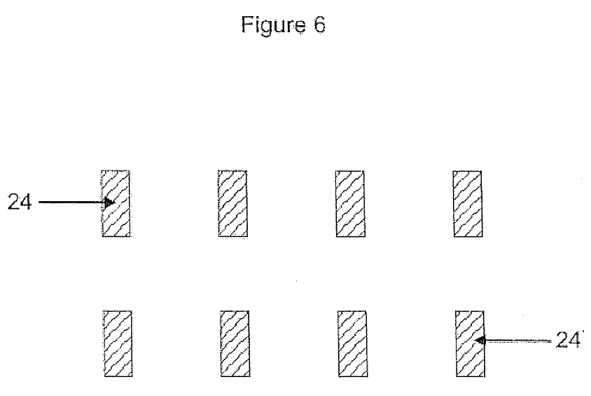

The dielectric insulating material 24 is screen printed overtop one side portion of the aluminum cathodes 44 to prevent short-circuiting when the conductive interconnecting material 26 is printed in a successive step. The strips of the conductive material 26 that are printed are shown in FIG. 6.

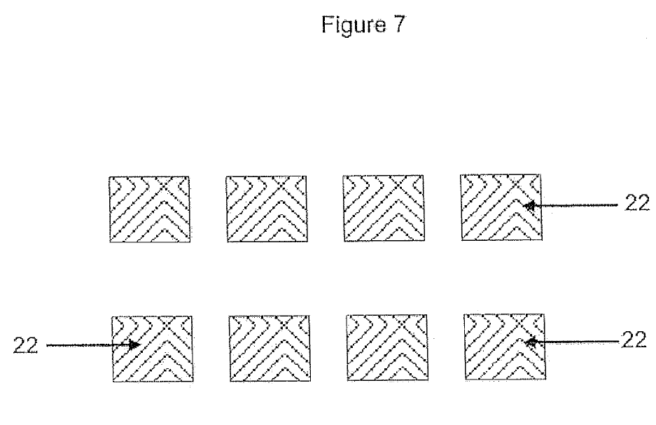

A conductive, semi-transparent valence hole injection material, such as Pedot/PSS, is screen printed over the active layer 20 to form the hole injection layer 22, which acts as the anode. The segments of the hole injection layer 22 that are printed are shown in FIG. 7.

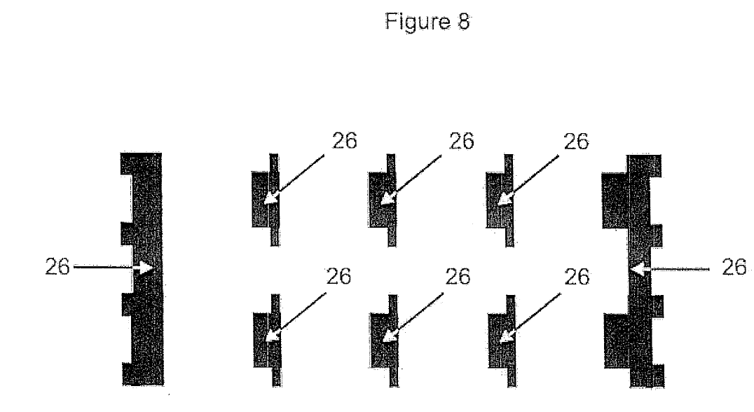

The device 40 is convection cured and then the electrically conductive interconnect material 26, e.g. silver, is screen printed in strips as shown in FIG. 8, making contact with the hole injection layer 22 on one side and the aluminum cathode 14 on the other side to complete the device 40. As shown in FIG. 9, the four cells 12 in each row are connected in series and the two rows are connected in parallel.

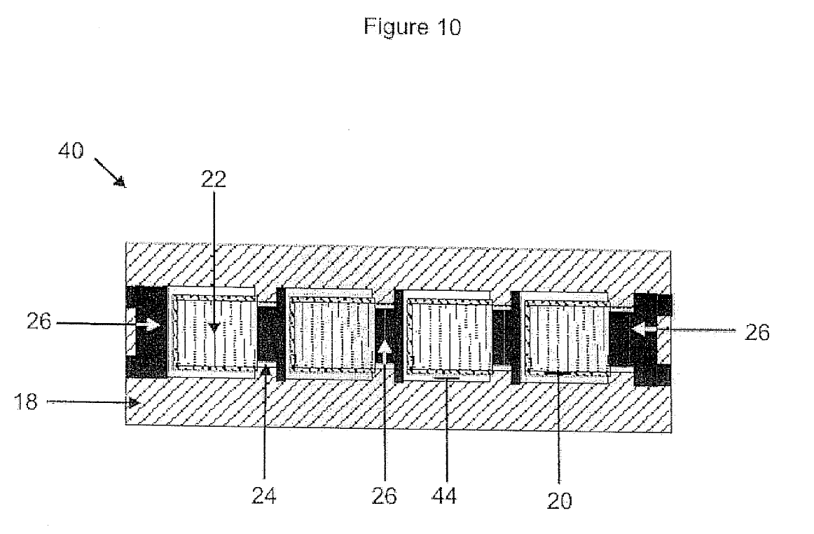

A photovoltaic cell 50 with a different layout is shown in FIG. 10 in which three rows of four cells 12 each are connected in series.

Although the manufacture of a photovoltaic device has been described by way of example above, it will be appreciated that the method can also be used for the manufacture of an electroluminescent device by substituting an appropriate light emitting polymer as the active layer 20.

Although certain preferred embodiments of the present invention have been shown and described in detail, it should be understood that various changes and modifications may be made therein without departing from the scope of the appended claims.

The claims which follow are to be considered an integral part of the present disclosure. The term “comprises” or “comprising”, as used herein and in the claims, has its customary non-restrictive meaning which denotes that in addition to any items to which the term relates, there may be included additional items not specifically mentioned.

I claim:

1. A process for manufacturing a photovoltaic or a light emitting polymer device, comprising:
providing a cathode of aluminum;
placing the cathode in an inert atmosphere and removing aluminum oxide formed on the aluminum prior to placement thereof in the inert atmosphere;
passivating the aluminum while still in the inert atmosphere by coating the aluminum with a passivation agent to prevent oxidation of the aluminum upon exposure to oxygen;
removing the passivated aluminum from the inert atmosphere;
providing an active layer of a photovoltaic or an electroluminescent material on the passivated aluminum; and
providing a valence hole injection layer over the active layer to form an anode.

2. The process of claim 1, wherein the inert atmosphere comprises a gas selected from one or more of the group consisting of nitrogen and argon.

3. The process of claim 1, wherein the step of removing aluminum oxide from the aluminum comprises treating the aluminum with a suitable etching medium.

4. The process of claim 3, wherein the etching medium comprises nitric acid.

5. The process of claim 1, wherein the passivation agent comprises an alkyl ether acetate.

6. The process of claim 5, wherein the passivation agent comprises butyl carbitol acetate.

7. The process of claim 1, wherein the cathode is in the form of an aluminum sheet or foil.

8. The process of claim 7, wherein the active layer is printed on the aluminum sheet or foil.

9. The process of claim 8, wherein the active layer is printed by means of screen printing, ink jet printing or gravure printing.

10. The process of claim 8, wherein the hole injection layer is printed on the active layer.

11. The process of claim 10, wherein the hole injection layer is printed by means of screen printing, ink jet printing or gravure printing.

12. The process of claim 7, wherein the cathode comprises a plurality of electrically isolated cathode cells which are cut from an aluminum sheet or foil and mounted on a substrate.

13. The process of claim 12, further comprising the step of printing a layer of electrically insulating material around each of the cathode cells.

14. The process of claim 13, wherein the cathode cells and the layer of insulating material are of the same thickness.

15. The process of claim 12, wherein the active layer is printed in discrete segments over the electrically isolated cathode cells.

16. The process of claim 15, wherein the segments of the active layer are printed by means of screen printing or ink jet printing.

17. The process of claim 15, wherein the hole injection layer is printed in discrete segments over the segments of the active layer.

18. The process of claim 17, wherein the segments of the hole injection layer are printed by means of screen printing, ink jet printing or gravure printing.

19. The process of claim 18, further comprising the step of printing a strip of electrically insulating material along one side of each of the segments of the active layer prior to printing the hole injection layer over the active layer to prevent short-circuiting.

20. The process of claim 19, further comprising the step of printing strips of electrically conductive material to interconnect the cathode cells.

21. A process for manufacturing a photovoltaic or a light emitting polymer device, comprising:
providing a plurality of electrically isolated cathode cells of aluminum sheet or foil on a substrate;
placing the substrate with the electrically isolated cathode cells in an inert atmosphere and removing aluminum oxide formed on the cathode cells prior to placement thereof in the inert atmosphere;
passivating the cathode cells while still in the inert atmosphere by coating the cathode cells with a passivation agent to prevent oxidation of the cathode cells upon exposure to oxygen;
removing the passivated cathode cells from the inert atmosphere;
printing discrete segments of an active layer of a photovoltaic or an electroluminescent material over each of the cathode cells; and
printing discrete segments of a valence hole injection layer over each of the segments of the active layer to form an anode for each cathode cell.

22. The process of claim 21, further comprising the step of printing an electrically insulating material along one side of each of the segments of the active layer prior to printing the hole injection layer over the active layer to prevent short-circuiting.

23. The process of claim 21, further comprising the step of printing strips of electrically conductive material to interconnect the cathode cells.

24. The process of claim 21, further comprising the steps of printing a layer of electrically insulating material around each of the cathode cells.
